(19) United States
(12) Patent Application Publication
(10) Pub. No.: US 2024/0320390 A1
(43) Pub. Date: Sep. 26, 2024

(54) SIMULATION SERVER BASED ON DIGITAL TWIN AND MANAGEMENT SYSTEM FOR MANUFACTURING LOGISTICS USING THE SIMULATION SERVER

(71) Applicant: Samsung Display Co., LTD., Yongin-si (KR)

(72) Inventor: Yonggu KIM, Yongin-si (KR)

(21) Appl. No.: 18/394,954

(22) Filed: Dec. 22, 2023

(30) Foreign Application Priority Data
Mar. 22, 2023 (KR) 10-2023-0037537

(51) Int. Cl. G06F 30/20

(52) U.S. Cl. CPC G06F 30/20

(57) ABSTRACT

A simulation server includes: a database configured to store history data including an occupancy rate of an actual storage unit, wherein the database includes image data for a virtual storage unit corresponding to the actual storage unit to drive simulation using the digital twin; and a simulator apparatus configured to perform the simulation based on the history data and the image data, where the simulator apparatus is further configured to obtain a change amount of an occupancy rate of the virtual storage unit during the simulation, and change or maintain a maximum storage capacity of the virtual storage unit based on the change amount.

This application claims priority to Korean Patent Application No. 10-2023-0037537, filed on Mar. 22, 2023, and all the benefits accruing therefrom under 35 U.S.C. § 119, the content of which in its entirety is herein incorporated by reference.

### BACKGROUND

### 1. Field

One or more embodiments relate to a simulation server based on a digital twin and a management system for manufacturing logistics using the simulation server, and more particularly, to a simulation server based on a digital twin and a management system for manufacturing logistics using the simulation server to improve the logistics efficiency in a manufacturing process.

### 2. Description of the Related Art

With the rapid increase in interests in virtual reality (“VR”), augmented reality (“AR”), and mixed reality (“MR”), extended reality (“XR”) has been developed, and also, the market for services and apparatuses that provide users with an immersive experience is expanding daily.

As the digitalization of manufacturing processes has increased, the concept of a digital twin to create a digital image of a real object or process in near real time for a work site is attracting attention.

A digital twin is defined as an evolving digital profile that records the past and present activities of a physical object or process to help optimize business performance. Digital twins are based on large, cumulative real-time, real-world data measurements across multiple dimensions.

The digital twin technology has been used in various fields such as display apparatus manufacturing and semiconductor apparatus manufacturing. Many studies have been conducted to effectively manage manufacturing logistics.

### SUMMARY

One or more embodiments include a simulation server based on a digital twin and a management system for manufacturing logistics using the simulation server to improve the logistics efficiency in a manufacturing process. However, such a technical problem is just an example, and the disclosure is not limited thereto.

Additional aspects will be set forth in part in the description which follows and, in part, will be apparent from the description, or may be learned by practice of the presented embodiments of the disclosure.

According to one or more embodiments, a simulation server includes: a database configured to store history data including an occupancy rate of an actual storage unit, wherein the database includes image data for a virtual storage unit corresponding to the actual storage unit to perform simulation by using a digital twin; and a simulator apparatus configured to perform the simulation based on the history data and the image data, where the simulator apparatus is further configured to obtain a change amount of an occupancy rate of the virtual storage unit during the simulation, and change or maintain a maximum storage capacity of the virtual storage unit based on the change amount.

The history data may be information about the occupancy rate of the actual storage unit over time, and may be obtained before a reference point-in-time.

The actual storage unit may include a plurality of storage modules, the image data for the virtual storage unit may include module image data corresponding to the plurality of storage modules, respectively, and the module image data may be added to or removed from the simulation.

The maximum storage capacity of the virtual storage unit may be proportional to a total number of the module image data during the simulation.

The simulator apparatus may be further configured to obtain first comparison information of the occupancy rate of the virtual storage unit and a first preset occupancy rate after a reference time elapses during the simulation, and change the total number of the module image data during the simulation based on the first comparison information.

When the occupancy rate of the virtual storage unit is less than the first preset occupancy rate after the reference time elapses during the simulation, the simulator apparatus may be configured to reduce the total number of the module image data during the simulation.

When the occupancy rate of the virtual storage unit is greater than the first preset occupancy rate after the reference time elapses during the simulation, the simulator apparatus may be further configured to obtain second comparison information of an occupancy rate of the virtual storage unit and a second preset occupancy rate.

The second preset occupancy rate may be greater than the first preset occupancy rate.

When the occupancy rate of the virtual storage unit is less than the second preset occupancy rate after the reference time elapses during the simulation, the simulator apparatus may be further configured to maintain the maximum storage capacity of the virtual storage unit.

When the occupancy rate of the virtual storage unit is greater than the second preset occupancy rate after the reference time elapses during the simulation, the simulator apparatus may be further configured to increase the total number of the module image data during the simulation.

According to one or more embodiments, a management system for manufacturing logistics includes: a sensing system configured to obtain, over time, occupancy state information of each of a plurality of storage modules constituting an actual storage unit located in a preset area; a simulation server including a database configured to store history data including the occupancy state information obtained over time, where the database includes image data for a virtual storage unit corresponding to the actual storage unit, and a simulator apparatus configured to perform digital twin-based simulation based on the history data and the image data; and a monitoring system configured to output the digital twin-based simulation, where the simulator apparatus is further configured to obtain a change amount of an occupancy rate of the virtual storage unit during the simulation, change or maintain a maximum storage capacity of the virtual storage unit based on the change amount, and create result data including the changed or maintained maximum storage capacity, and the monitoring system may be further configured to output the result data.

The management system of manufacturing logistics may further include: at least one automated guided vehicle (“AGV”) configured to travel in the preset area, and an AGV control server configured to control the at least one automated guided vehicle.

The history data may be information of an occupancy rate of the actual storage unit over time and is obtained before a reference point-in-time.

The actual storage unit may include the plurality of storage modules, and the image data for the virtual storage unit may include module image data corresponding to the plurality of storage modules, respectively, and the module image data may be added or removed from the simulation.

The maximum storage capacity may be proportional to a total number of module image data during the simulation.

The simulator apparatus may be further configured to obtain first comparison information of the occupancy rate of the virtual storage unit and a first preset occupancy rate after a reference time elapses during the simulation, and change a total number of the module image data during the simulation based on the first comparison information.

When the occupancy rate of the virtual storage unit is less than the first preset occupancy rate after the reference time elapses during the simulation, the simulator apparatus may be further configured to reduce the total number of the module image data during the simulation.

When the occupancy rate of the virtual storage unit is greater than the first preset occupancy rate after the reference time elapses during the simulation, the simulator apparatus may be further configured to obtain second comparison information of the occupancy rate of the virtual storage unit and a second preset occupancy rate after the reference time elapses during the simulation.

The second preset occupancy rate may be greater than the first preset occupancy rate.

When the occupancy rate of the virtual storage unit is less than the second preset occupancy rate after the reference time elapses during the simulation, the simulator apparatus may be further configured to transfer the maximum storage capacity to the monitoring system, and the monitoring system may be configured to output the maximum storage capacity.

When the occupancy rate of the virtual storage unit is greater than the second preset occupancy rate after the reference time elapses during the simulation, the simulator apparatus may be further configured to increase the total number of the module image data.

The monitoring system may be configured to perform a manufacturing process that uses the actual storage unit changed based on the result data, and receive an occupancy rate of the actual storage unit while performing the manufacturing process.

The monitoring system may be further configured to obtain third comparison information of the occupancy rate of the actual storage unit and a third preset occupancy rate while performing the manufacturing process, and control driving of target equipment or create feedback data based on the third comparison information.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic conceptual view of a management system for manufacturing logistics according to an embodiment;

FIG. 2 is a schematic conceptual view of a simulator apparatus of FIG. 1;

FIG. 3 is a schematic view showing a manufacturing process scenario that utilizes a management system for manufacturing logistics according to an embodiment;

FIG. 4 is a schematic flowchart showing a simulation process of a simulation server included in the management system for manufacturing logistics of FIG. 1;

FIG. 5 is a schematic flowchart showing a process of generating feedback data based on result data generated by a simulation server included in the management system for manufacturing logistics of FIG. 1;

FIGS. 6 and 7 are schematic views for explaining a scenario of controlling a path of an automated guided vehicle in an automated guided vehicle control server of FIG. 1; and

FIG. 8 is a schematic conceptual view of an automated guided vehicle control server of FIG. 1.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “Or” means “and/or.” It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, certain embodiments will be illustrated in the drawings and described in the written description. Effects and features of the disclosure, and methods for achieving them will be clarified with reference to embodiments described below in detail with reference to the drawings. However, the disclosure is not limited to the following embodiments and may be embodied in various forms.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Hereinafter, embodiments will be described with reference to the accompanying drawings, wherein like reference numerals refer to like elements throughout and a repeated description thereof is omitted.

As used herein, when various elements such as a layer, a region, a plate, and the like are disposed “on” another element, not only the elements may be disposed “directly on” the other element, but another element may be disposed therebetween. In addition, sizes of elements in the drawings may be exaggerated or reduced for convenience of explanation. As an example, the size and thickness of each element shown in the drawings are arbitrarily represented for convenience of description, and thus, the disclosure is not necessarily limited thereto.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different orientations that are not perpendicular to one another.

Hereinafter, a simulation server based on a digital twin and a management system of manufacturing logistics using the simulation server according to an embodiment are described in detail.

For reference, a simulation server based on a digital twin and a management system of manufacturing logistics using the simulation server according to an embodiment may reflect states of actual objects and field users in a physical space in real-time into an on-site twin model of a virtual three-dimensional space created by scanning the physical space of an actual work site, thereby providing a method of allowing a remote manager to monitor the site through the on-site twin model.

Furthermore, a simulation server based on a digital twin and a management system of manufacturing logistics using the simulation server according to an embodiment may be configured to obtain information on a logistics state at a future point-in-time through simulation based on the on-site twin model. In addition, a simulation server based on a digital twin and a management system of manufacturing logistics using the simulation server according to an embodiment may be configured to obtain information on quantity control or optimal number of storage units (or storage modules) for storage of work in progress (“WIP”) for manufacturing logistics management based on the acquired information on the logistics state at a future point-in-time. For reference, work in progress may denote an article in the process of production during a manufacturing process.

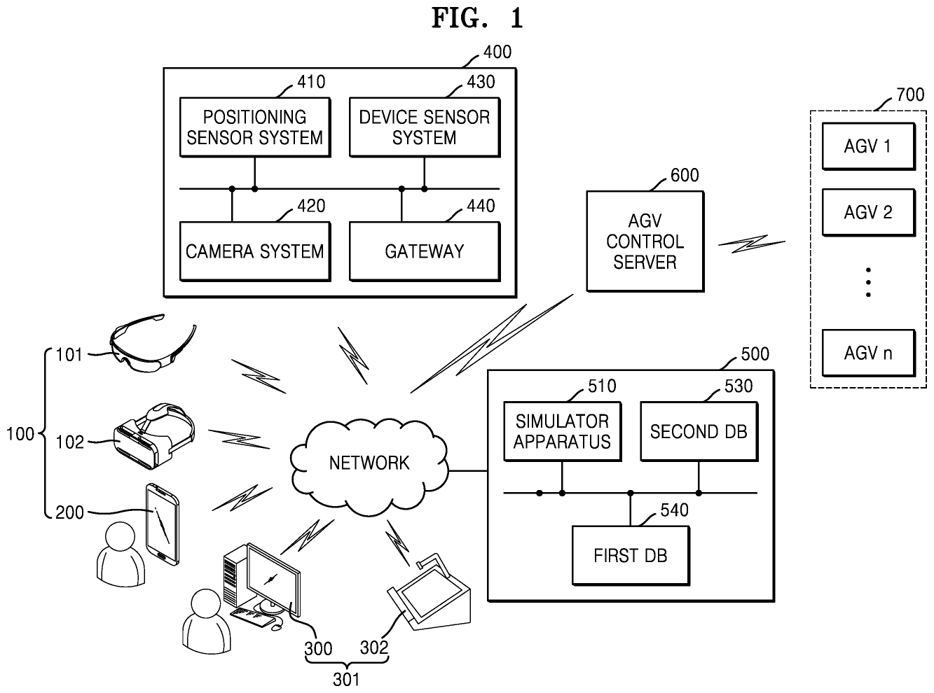

FIG. 1 is a schematic conceptual view of a management system of manufacturing logistics according to an embodiment. A management system of manufacturing logistics according to an embodiment may be a system capable of managing logistics carried during a manufacturing process based on digital twin technology.

As shown in FIG. 1, the management system of manufacturing logistics according to an embodiment may include a user terminal 100, a monitoring system 301, a sensing system 400, a simulation server 500, an automated guided vehicle (AGV) control server 600, and an automated guide vehicle 700.

The user terminal 100 may mean a computing device used by a user at a manufacturing site. As an example, the user terminal 100 may include wearable type computing devices 101 and 102. In addition, the user terminal 100 may include a mobile type computing device 200. A mobile type computing device may be a mobile apparatus such as smartphones, tablet personal computers (“PCs”), and notebook computers. The mobile type computing device may be configured to capture images of a physical space around a user at a manufacturing site with an image sensor, display virtual content by matching a pre-produced digital twin image or digital twin image with the physical space, and provide an augmented reality environment to the user.

The sensing system 400 may include a positioning sensor system 410, a device sensor system 430, a camera system 420, a gateway 440, and the like. The sensing system 400 may include various sensors configured to sense and measure various information (e.g., environment, machine facilities, and site user information) about the physical space of the site. As an example, the sensing system 400 may include at least one of a temperature sensor, a humidity sensor, a pressure sensor, a flow sensor, a magnetic sensor, an optical sensor, an acoustic sensor, an image sensor, a current sensor, and a gas sensor disposed in the site.

The positioning sensor system 410 may be configured to detect position information of a site user in real time. The positioning sensor system 410 may be configured to detect the position information of site users based on a photoelectric sensor, an ultrasonic sensor, a gate type sensor, a thermal sensor, a laser sensor, a lidar sensor, a Wi-Fi sensor, a beacon sensor, an ultra-wide band (“UWB”) sensor, a Bluetooth sensor, an image analysis sensor, an RFID sensor, and technologies such as PDR, and GPS. These are examples, and in the present specification, the positioning sensor system 410 may include various positioning sensor equipment in addition to the sensors described above.

The camera system 420 includes an omnidirectional camera 421 (e.g., a 360-degree camera) that takes pictures in all directions from an installed position, and/or at least one remote control camera 423 (for example, a pan-tilt-zoom (“PTZ”) camera) capable of changing a shooting area under the control of a remote manager.

In addition, the camera system 420 may be disposed in the site, and a shooting direction and zoom in/out of the camera system 420 may be remotely controlled. Accordingly, the camera system 420 may be configured to acquire a site image for a shooting direction and an enlarged/reduced shooting area automatically or according to control of a manager.

The device sensor system 430 may include sensors configured to sense various information of apparatuses disposed in the site. The device sensor system 430 may include an Internet of Things (“IOT”) sensor disposed in a device, and sensors configured to sense the environment around the device to obtain device-related information. As an example, the device sensor system 430 may include a sensor disposed inside a storage unit or around the storage unit, and be configured to sense an occupancy state or a non-occupancy state of storage modules constituting the storage unit through the sensor. That is, the device sensor system 430 may be configured to obtain information for an occupancy state or a non-occupancy state of each of the plurality of storage modules constituting the storage unit, and transmit the obtained information to the monitoring system 301 or the simulation server 500 using the gateway 440. The information for an occupancy state or a non-occupancy state may be defined as occupancy state information.

As described above, sensing data obtained through the positioning sensor system 410, the camera system 420, the device sensor system 430, and the camera system 420 may be transmitted to the gateway 440 including at least one access point. The gateway 440 may be configured to collect obtained sensing data and transmit the collected sensor data to the simulation server 500 or the monitoring system 301.

The monitoring system 301 may be configured to remotely monitor the site through the on-site twin model reflecting the site physical space according to the control of an installed monitoring application. As an example, the monitoring system 301 may be configured to display virtual content created based on sensing data measured from an actual object in the physical space at the actual site, and monitor the actual object in real time.

The monitoring system 301 may include a control apparatus 300 configured to control facilities on the site, and a display apparatus 302 configured to output various information. In this case, the control apparatus 300 may be configured to not only transmit/receive data to/from other elements of the embodiment but also control an operation of manufacturing facilities provided to the site. The display apparatus 302 is just one example of an information interface apparatus between a user and equipment, and may be replaced by another input/output interface apparatus.

In addition, the monitoring system 301 may be configured to receive various information from the sensors installed in on-site facilities. As an example, the monitoring system 301 may be configured to receive information related to the occupancy rate of the storage unit from the storage unit among the on-site facilities. The information received by the monitoring system 301 may be output through the display apparatus 302 and the like, and transferred to a user or a manager through the display apparatus 302 and the like.

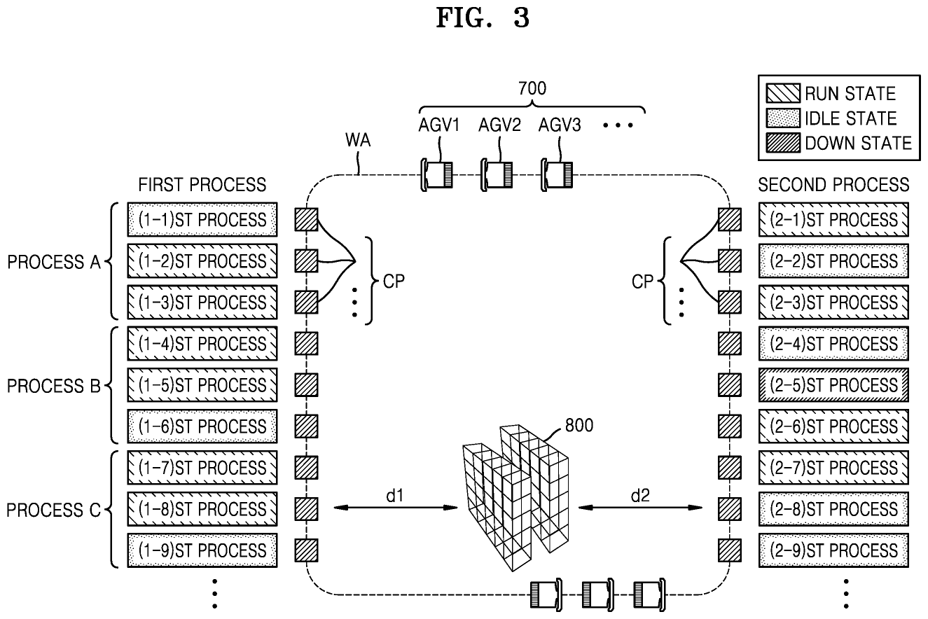

An actual storage unit 800 (see FIG. 3) may be configured to store work in process managed in the manufacturing process for preset time period or temporarily. Because the actual storage unit 800 may include modular storage modules that may be assembled, an occupancy rate of the actual storage unit 800 may be changed in real-time according to the quantity of works in the process stored in a storage box. In addition, a maximum storage capacity of the actual storage unit 800 capable of storing works in the process may be changed.

In addition, each of the storage modules constituting the actual storage unit 800 may include a sensor configured to sense an occupancy state or a non-occupancy state. Alternatively, an occupancy state or a non-occupancy state of the actual storage unit 800 may be sensed by the device sensor system 430 or the camera system 420 of the sensing system 400.

Accordingly, the monitoring system 301 may be configured to receive information for an occupancy state or a non-occupancy state of the actual storage unit 800 or each of the storage modules from the sensing system 400, and obtain information such as an occupancy rate, which is a ratio of a currently occupied capacity to an entire storage capacity, based on the received information. As an example, in the present specification, an occupancy rate may mean a ratio of a total number of storage modules occupied by works in the process to a total number of all storage modules included in the actual storage unit 800.

In addition, the monitoring system 301 may be a control system configured to control facilities operating in the site or sense a state of the facilities operating in the site and control the operation of the facilities based on the information received from the sensing system 400. The monitoring system 301 may be configured to control the operation of the facilities based on a user's input or control the operation of the facilities based on a command input in advance or a learned algorithm.

The simulation server 500 may be configured to create the on-site twin model corresponding to the on-site physical space in a virtual three-dimensional space based on data obtained by 3-dimension scanning the on-site physical space. As an example, the simulation server 500 may be configured to create the on-site twin model obtained by modeling virtual objects corresponding to actual objects in the physical space in the virtual three-dimensional space based on images of the on-site physical space and space information (e.g., depth data) obtained by scanning the position of the actual objects located in the physical space. In addition, the simulation server 500 may be configured to create the on-site twin model while reflecting an input of a remote manager from the monitoring system 301.

The simulation server 500 may include a simulator apparatus 510 configured to drive simulation and a database (“DB”) configured to store data required to drive the simulation of the simulator apparatus 510. In this case, the database (DB) may include a first database (DB) 540 configured to store image data corresponding to the facilities installed in the site, and a second database (DB) 530 configured to store history data including an occupancy rate of the actual storage unit 800 installed in the site. Although it may be described that the database (DB) is divided into a plurality of databases, for convenience of description, the data may be stored and managed by one database (DB).

An automated guided vehicle 700 is an unmanned mobile vehicle that transports and loads and unloads various cargoes in an indoor or outdoor work area (workplace), and may be an autonomous vehicle, a mobile robot, or the like. The automated guided vehicle 700 may be provided singly or in plurality. As an example, as shown in FIG. 1, the automated guided vehicle 700 may include a plurality of first to n-th automated guided vehicles AGV1 to AGVn, and each of the first to n-th automated guided vehicles AGV1 to AGVn may be configured to perform assigned tasks in the work area. The automated guided vehicle 700 may be configured in various methods such as a pallet (trolley) lower pulling method, a forklift method, a mini-load method, and a front hook pulling method.

The automated guided vehicle 700 may be configured to receive path data from the AGV control server 600 and move on nodes according to the path data. The path data may include position data of a node (the next node) to which the automated guided vehicle 700 is to move from a current node. The automated guided vehicle 700 may maintain a driving direction to move to the next node, or change a driving direction to move to the next node. Accordingly, the automated guided vehicle 700 may be configured to move along a selected path among a plurality of candidate paths. A selected path may be succession of edges connecting nodes on which the automated guided vehicle 700 actually moves. Detailed description of the movement of the automated guided vehicle 700 and the AGV control server 600 controlling the same is made below.

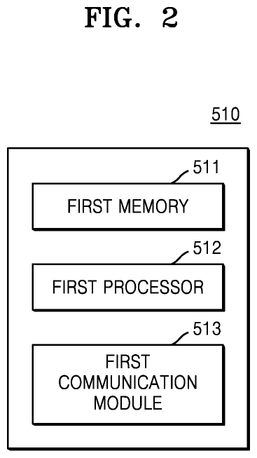

FIG. 2 is a schematic conceptual view of the simulator apparatus 510 of FIG. 1.

As shown in FIG. 2, the simulator apparatus 510 may include a first memory 511, a first processor 512, and a first communication module 513.

The simulator apparatus 510 may include a first memory 511, a first communication module 513, and a first processor 512. Hereinafter, in the present specification, it may be understood that an operation, a command, a control, and the like performed by the simulator apparatus 510 are performed by the first processor 512 configured to perform commands stored in the first memory 511, and data or information created by the first processor 512 is transferred to an external apparatus (e.g., a user terminal, the monitoring system 301, the AGV control server 600, and the like) by the communication module.

The first processor 512 may be configured to control other elements by executing the commands stored in the first memory 511. The first processor 512 may be configured to perform the commands stored in the first memory 511.

The first processor 512 is an element configured to perform calculations and control another apparatus. Mainly, the first processor 512 may denote a central processing unit (“CPU”), an application processor (“AP”), a graphics processing unit (“GPU”), or the like. In addition, the CPU, the AP, or the GPU may include one or more cores therein, and the CPU, the AP, or the GPU may be configured to operate using operation voltages and clock signals. While the CPU or the AP includes several cores optimized for serial processing, the GPU may include thousands of smaller and more efficient cores designed for parallel processing.

The first processor 512 may be configured to provide proper information or function to a user or process proper information or function by processing signals, data, and information input or output through the elements described above, or driving application programs stored in the first memory 511.

The first memory 511 is configured to store data supporting various functions of the simulator apparatus 510. The first memory 511 may be configured to store a plurality of application programs (or applications) driven by the simulator apparatus 510, data and commands for operations of the simulator apparatus 510. At least some of the application programs may be downloaded from an external server through wireless communication. In addition, the application program may be stored in the first memory 511, installed in the simulator apparatus 510, and driven by the first processor 512 to perform an operation (or a function) of the simulator apparatus 510.

The first memory 511 may include at least one type storage medium among a flash memory type, a hard disk type, a solid state disk type (“SSD”), a silicon disk drive type (“SDD”), and a multimedia card micro type, card-type memory (e.g., “SD” or “XD” memory, etc.), random access memory (“RAM”), static random access memory (“SRAM”), read-only memory (“ROM”), electrically erasable programmable read-only memory (“EEPROM”), programmable read-only memory (“PROM”), a magnetic memory, a magnetic disk, and an optical disk. In addition, the first memory 511 may include a web storage configured to perform a storage function on the Internet.

For reference, depending on the case, the function or role of the first DB 540 and the second DB 530 may be implemented in the first memory 511 of the simulator apparatus 510.

The first communication module 513 is configured to transmit/receive information to/from a base station or a camera including a communication function through an antenna. The first communication module 513 may include a modulator, a demodulator, a signal processor, and the like. Alternatively, the first communication module 513 may be configured to perform a wired communication function.

Wireless communication may refer to communication that uses a wireless communication network using communication facilities previously installed by telecommunication companies and frequencies of the communication facilities. In this case, the first communication module 513 may be used not only in code division multiple access (“CDMA”), frequency division multiple access (“FDMA”), time division multiple access (“TDMA”), orthogonal frequency division multiple access (“OFDMA”), single carrier frequency division multiple access (“SC-FDMA”), and the like, but also in 3rd generation partnership project (“3GPP”), long term evolution (“LTE”), and the like. In addition, the first communication module 513 may be used in not only 5G communication currently commercialized, but also 6G communication scheduled for commercialization in the future. However, in the present specification, a pre-installed communication network may be utilized without being bound by such a wireless communication method.

In addition, as short range communication technology, Bluetooth, Bluetooth Low Energy (“BLE”), Beacon, radio frequency identification (“RFID”), Near Field Communication (“NFC”), Infrared Data Association (“IrDA”), Ultra-Wideband (“UWB”), ZigBee, etc. may be used.

FIG. 3 is a schematic view showing a manufacturing process scenario that utilizes a management system of manufacturing logistics according to an embodiment. For reference, a title of each process and a total number of processes shown in FIG. 3 are just examples, for understanding.

As shown in FIG. 3, an example of a manufacturing process scenario that utilizes a management system of manufacturing logistics according to an embodiment is described below.

The manufacturing process scenario may roughly include a first process and a second process. The first process and the second process may be processes that are spatially and/or temporally separated from each other.

As described above, due to spatial and/or temporal separation between the first process and the second process, work in the process may occur between the processes. As an example, work in the process produced in the second process may be moved by an automated guided vehicle to a process line in which the first process is performed.

In the case where work in the process is moved from a process line of the second process to a process line of the first process, the first process may not perform a subsequent manufacturing process using the work in the process. As an example, the case where one of processes of the first processor 512 is stopped or the case where works in the process are excessively supplied and logistics congestion occurs may occur. Accordingly, to prevent these cases, the actual storage unit 800 configured to store work in the process may be installed.

The management system of manufacturing logistics according to an embodiment may include the actual storage unit 800 capable of storing work in the process. In this case, the actual storage unit 800 may be configured to store work in the process as much as the maximum storage capacity. The automated guide vehicles may be configured to move work in the process to the actual storage unit 800 or move work in the process of the actual storage unit 800 to a required process according to a command of the AGV control server 600.

The actual storage unit 800 may be arranged to be apart by a first distance from a process line of the first process. In addition, the actual storage unit 800 may be arranged to be apart by a second distance from a process line of the second process. The first distance and the second distance may be changed.

As an example, in the case where the delay frequency of the process in the first process is greater than the delay frequency of the process in the second process, the first distance may be less than the second distance. Accordingly, the automated guided vehicle may be configured to swiftly move excessive work in the process to the actual storage unit 800, and time consumed for the process may be reduced.

As an example, the first process may be subdivided into a process A, a process B, a process C, and the like, and the process A may be subdivided into a (1-1)st process, a (1-2)nd process, a (1-3)rd process, and the like. Various situations may occur depending on each process, and thus a process to be performed in a specific process may be delayed. In this case, works in the process occurring in the previous process of the process in which the process is delayed may be delayed without being transferred to the next process.

In the case where the works in the process are delayed without being transferred to the next process, the automated guided vehicle or on-site personnel may move and store the work in the process in the actual storage unit 800. Accordingly, it is desirable to accurately predict the quantity of works in the process that are delayed and piled up according to the frequency of occurrence of defects in each process, the time required for the process, etc., and prepare the actual storage unit 800 with sufficient capacity to match the predicted quantity.

However, due to space constraints, process changes, and equipment replacement, the section in which work in the process is delayed may continue to change. Accordingly, the actual storage unit 800 may be configured in an assembly-type modular manner, and needs to be reassembled or dismantled according to a section in which work in the process is delayed.

As described above, to install the actual storage unit 800 with an appropriate capacity, a simulation may be executed with previous data of a reference point-in-time before starting the process. When information on the capacity of the actual storage unit 800 required according to the simulation results is obtained, the capacity of the actual storage unit 800 of an assembly-type modular manner may be changed based on the obtained information.

As described above, to obtain information on the capacity of the actual storage unit 800 required, the simulation server 500 may include the simulator apparatus 510 and the DB.

The DB may be configured to store history data including occupancy information of the actual storage unit 800 and may include image data for a virtual storage unit corresponding to the actual storage unit 800 to drive simulation that uses a digital twin. Specifically, the history data may be stored in the first DB 540, and the image data for driving the simulation may be stored in the second DB 530.

The history data may denote data obtained before the reference point-in-time. As an example, the history data may include information on the occupancy rate of the actual storage unit 800 over time. As an example, the history data may include information on a change amount of the occupancy rate of the actual storage unit 800. As an example, the history data is information on the occupancy rate of the actual storage unit 800 over time and may be data obtained before the reference point-in-time. Specifically, a starting point of the process may be defined as the reference point-in-time, and data obtained by arranging information on the occupancy rate of the actual storage unit 800 before starting the process in time series may be referred to as history data. As an example, when Feb. 27, 2023 is defined as the reference point-in-time, history data may include information for occupancy figures over time such as an occupancy rate at 0:00 (0 o'clock) on Feb. 26, 2023, an occupancy rate at 1:00 (1 o'clock), an occupancy rate at 2:00 (2 o'clock), and the like. Time units for arranging in time series may be variously set, such as seconds, minutes, and hours.

Image data for the virtual storage unit may be virtual image data during the simulation corresponding to the actual storage unit 800. Image data for the virtual storage unit may be configured to reflect a change of the actual storage unit 800 in the site in real-time or after a preset time. Conversely, when a change for the virtual storage unit is input using image data for the virtual storage unit, a change for the actual storage unit 800 may occur according to the input change. In this case, the actual storage unit 800 may be changed by an on-site personnel or on-site automation equipment.

Image data for the virtual storage unit may be image data created in advance corresponding to the actual storage unit 800. The actual storage unit 800 may include a plurality of storage modules, and the plurality of storage modules may be added or removed. Accordingly, during the simulation, image data for the virtual storage unit may also include image data for a plurality of virtual storage modules, and the image data for the plurality of virtual storage modules may be also added or removed. In the present specification, image data for each of the plurality of virtual storage modules may be referred to as module image data. During the simulation, as module image data is added or removed, a maximum storage capacity of the virtual storage unit may be increased or reduced during the simulation.

The simulator apparatus 510 may be configured to execute simulation based on history data and image data for the virtual storage unit. The simulator apparatus 510 may be configured to obtain a change amount of an occupancy rate of the virtual storage unit during the simulation, and change or maintain a maximum storage capacity of the virtual storage unit based on the change amount of the occupancy rate of the virtual storage unit.

Changing the maximum storage capacity of the virtual storage unit may mean that module image data for the plurality of virtual storage modules of the virtual storage unit is added or removed. When a total number of module image data is reduced during the simulation, a maximum storage capacity of the virtual storage unit may be reduced together, and when a total number of module image data increases, a maximum storage capacity of the virtual storage unit may increase together. Maintaining a maximum storage capacity of the virtual storage unit may be maintaining a total number of module image data.

The simulator apparatus 510 may be configured to obtain first comparison information of an occupancy rate of the virtual storage unit and a first preset occupancy rate after a reference time elapses during the simulation, and change a total number of the module image data during the simulation based on the first comparison information. The first comparison information is information that compares an occupancy rate of the virtual storage unit with the first preset occupancy rate, and may be information that an occupancy rate of the virtual storage unit is greater or less than (or equal to) the first preset occupancy rate. In this case, the reference time is a time determined by a user and may be a set value that may be changed and input by a user according to a desired result value.

As an example, when the occupancy rate of the virtual storage unit is less than the first preset occupancy rate (e.g., about 60%) after the reference time elapses during the simulation, the simulator apparatus 510 may be configured to reduce a total number of module image data during the simulation. A specific example is described below.

When the occupancy rate of the virtual storage unit is greater than or equal to the first preset occupancy rate after the reference time elapses during the simulation, the simulator apparatus 510 may be configured to obtain second comparison information of an occupancy rate of the virtual storage unit and a second preset occupancy rate. The second comparison information is information that compares an occupancy rate of the virtual storage unit with the second preset occupancy rate, and may be information that an occupancy rate of the virtual storage unit is greater or less than the second preset occupancy rate. In this case, the second preset occupancy rate may be greater than the first preset occupancy rate. In addition, the reference time is a time determined by a user and may be a set value that may be changed and input by a user according to a desired result value.

As an example, when the occupancy rate of the virtual storage unit is less than or equal to the second preset occupancy rate (e.g., about 80%) after the reference time elapses during the simulation, the simulator apparatus 510 may be configured to maintain a total number of module image data during the simulation.

When the occupancy rate of the virtual storage unit is less than or equal to the second preset occupancy rate (e.g., about 80%) after the reference time elapses during the simulation, the simulator apparatus 510 may be configured to maintain a maximum storage capacity of the virtual storage unit.

When the occupancy rate of the actual storage unit 800 is greater than the second preset occupancy rate (e.g., about 60%) after the reference time elapses during the simulation, the simulator apparatus 510 may be configured to increase a total number of module image data during the simulation. When a total number of module image data increases, a maximum storage capacity of the virtual storage unit may also increase.

As described above, a total number of module image data obtained by the simulator apparatus 510 may be stored as result data or transmitted to another apparatus. As an example, the result data may be transmitted to the monitoring system 301, and the monitoring system 301 may be configured to output the result data. That is, the monitoring system 301 may be configured to display or output a maximum storage capacity of the virtual storage unit to a user.

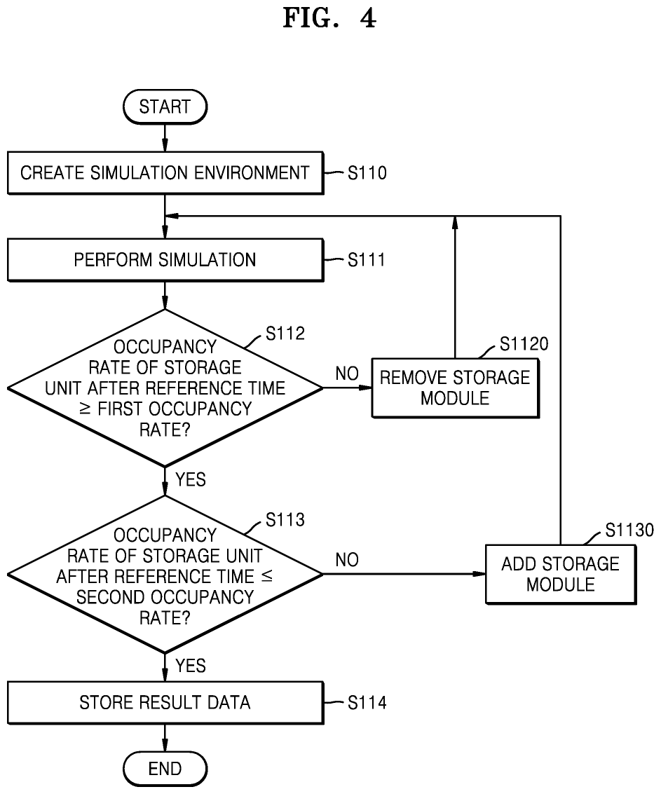

FIG. 4 is a schematic flowchart showing a simulation process of the simulation server included in the management system of manufacturing logistics of FIG. 1.

For convenience of description, a subject performing each operation is described as the simulation server 500, but may be the simulator apparatus 510 or the first process included in the simulator apparatus 510.

As shown in FIG. 4, the simulation server 500 of the management system of manufacturing logistics according to an embodiment may be configured to create a simulation environment (S110).

The creation of the simulation environment may be establishing a simulation environment based on data stored in the DB. Other information required to create a simulation environment may be input by a user or replaced by a preset set value.

As an example, the simulation environment may be created based on image data of the virtual storage unit and module image data of each of the plurality of storage modules constituting the virtual storage unit. In this case, a total number of the plurality of storage modules may be calculated based on a maximum storage capacity of the actual storage unit 800 obtained in advance and stored. That is, assuming that a maximum storage capacity of the actual storage unit 800 is about 10 and a storage capacity of one storage module is about 1, a total number of storage modules included in the actual storage unit 800 may be about 10.

In addition, a simulation environment may be created based on information on processes of the first process and the second process of FIG. 3. In addition, a simulation environment may be created based on information on the automated guided vehicles 700 configured to move works in the process and the AGC control server.

As described above, a simulation environment may be a digital twin environment implemented based on all information of the processes to be simulated.

The simulation server 500 may be configured to drive simulation based on a simulation environment (S111). Data that is output as a result value when driving the simulation may be a capacity occupied by work in the process compared to a maximum storage capacity of the actual storage unit 800.

The simulation server 500 may be configured to drive simulation and then create first comparison information of an occupancy rate of the actual storage unit 800 and the first preset occupancy rate after the reference time (S112). As an example, the first preset occupancy rate may be about 60%. In the case where the actual storage unit 800 is installed, because the actual storage unit 800 occupies a space inside a factory while the manufacturing process is performed, only an appropriate amount needs to be installed. When an occupancy rate of the actual storage unit 800 is less than 60%, it is required to remove at least one storage module and secure a space inside the factory.

Accordingly, when an occupancy rate of the actual storage unit 800 is less than the first preset occupancy rate after the reference time as a result of creating the first comparison information, the current capacity of the actual storage unit 800 is desirable to be reduced. When an occupancy rate of the actual storage unit 800 is less than the first preset occupancy rate after the reference time as a result of creating the first comparison information, at least one storage module may be removed during the simulation among the plurality of storage modules (S1120). After removing the at least one storage module, the simulation server 500 may be configured to perform the simulation again based on a changed maximum storage capacity of the actual storage unit 800.

When an occupancy rate of the actual storage unit 800 is greater than the first preset occupancy rate after the reference time as a result of creating the first comparison information, the simulation server may be configured to create the second comparison information of an occupancy rate of the actual storage unit 800 and the second preset occupancy rate after the reference time (S113). As an example, the second preset occupancy rate may be about 80%. When an occupancy rate of the actual storage unit 800 is greater than 80%, work in the process exceeding a maximum capacity of the actual storage unit 800 occurs to influence the entire manufacturing process. Accordingly, when an occupancy rate of the actual storage unit 800 is greater than 80%, a maximum storage capacity of the actual storage unit 800 is desirable to be increased. The simulation server 500 may be configured to add at least one storage module during the simulation (S1130), and perform the simulation again based on the changed maximum storage capacity of the actual storage unit 800.

The simulation server may be configured to create the second comparison information of an occupancy rate of the actual storage unit 800 and the second preset occupancy rate after the reference time (S113). When an occupancy rate of the actual storage unit 800 is less than the second preset occupancy rate after the reference time, a total number of storage modules or a maximum storage capacity of the actual storage unit 800 may be stored as result data (S114). That is, the simulation server 500 may be configured to perform simulation to maintain a filling rate of the actual storage unit 800 between the first preset occupancy rate and the second preset occupancy rate.

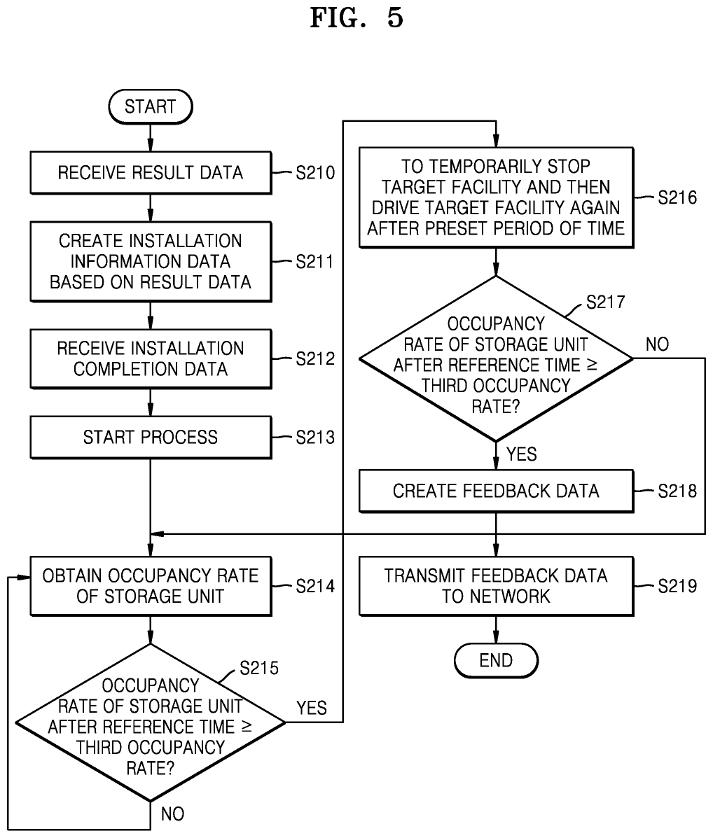

FIG. 5 is a schematic flowchart showing a process of generating feedback data based on result data generated by the simulation server included in the management system of manufacturing logistics of FIG. 1.

For convenience of description, although a subject that performs the process of creating the feedback data of FIG. 5 is described to be the monitoring system 301, the subject that performs the process of creating the feedback data may be a computing apparatus such as a processor that performs calculation of the monitoring system 301.

The monitoring system 301 may be configured to receive result data created by the simulation server 500 (S210). The monitoring system 301 may be configured to create installation information data based on the result data (S211). As an example, in the case where the result data includes information that n more storage modules are required, the monitoring system 301 may be configured to create installation information data including information that n more storage modules are required, and display the created installation information data through a display or output the created installation information data to a user. In this case, a subject that receives information may be a user working in the field or a terminal apparatus used by the user, but the subject may be an automated apparatus that performs the storage module installation.

A user may install n more storage modules based on the output installation information data. The monitoring system 301 may be configured to receive installation completion data based on a user's input (S212). In the case where a subject that installs the storage module is an automated apparatus, the monitoring system 301 may be configured to receive installation completion data from the automated apparatus.

As an example, a method of installing a storage module may denote adding s shelf that may divide a space to the actual storage unit 800, or adding or removing a modular storage module. However, there may be various methods.

The monitoring system 301 may be configured to start the manufacturing process scenario of FIG. 3. The monitoring system 301 may be configured to obtain an occupancy rate of the actual storage unit 800 through the sensing system 400 and the like.

The monitoring system 301 may be configured to create third comparison information by comparing an occupancy rate of the actual storage unit 800 with a third preset occupancy rate (S215). The third comparison information is information that compares an occupancy rate of the actual storage unit 800 with the third preset occupancy rate, and may be information that an occupancy rate of the actual storage unit 800 is greater or less than the third preset occupancy rate. In this case, the reference time is a time determined by a user and may be a set value that may be changed and input by a user according to a desired result value.

As an example, the third preset occupancy rate may be about 95%. When an occupancy rate of the actual storage unit 800 is greater than the third preset occupancy rate, the monitoring system 301 may be configured to temporarily stop a target facility and then drive the target facility again after a preset period of time (S216). Alternatively, when an occupancy rate of the actual storage unit 800 is greater than or equal to the third preset occupancy rate, the monitoring system 301 may be configured to output a guide message for temporarily stopping the target facility and then driving the target facility again after a preset period of time to a user.

The target facility denotes a facility that performs a process on work in the process to be stored in the actual storage unit 800, and preferably, may be a facility used in the last operation among facilities that perform a process on work in the process.

When the target facility is temporarily stopped, the manufacturing process of work in the process stored in the actual storage unit 800 is stopped, and the next process may be continuously performed using work in the process stored previously. As a result, works in the process stored in the actual storage unit 800 are used and exhausted, and an occupancy rate of the actual storage unit 800 may be reduced.

As an example, the third preset occupancy rate may be about 95%. When an occupancy rate of the actual storage unit 800 is less than the third preset occupancy rate, the monitoring system 301 may be configured to return to the previous operation again and obtain an occupancy rate of the actual storage unit 800 through the sensing system 400 and the like (S214).

The monitoring system 301 may be configured to be re-driven after temporary stoppage of the target facility, and create fourth comparison information that compares an occupancy rate of the actual storage unit 800 with the third preset occupancy rate (S217). The fourth comparison information is information that re-compares an occupancy rate of the actual storage unit 800 with the third preset occupancy rate, and may be information that an occupancy rate of the actual storage unit 800 is greater or less than the third preset occupancy rate. In this case, the reference time is a time determined by a user and may be a set value that may be changed and input by a user according to a desired result value.

However, to increase accuracy of measurement, the monitoring system 301 may be configured to obtain an occupancy rate of the actual storage unit 800 as many as a preset number of times or more and compare the occupancy rate with the third preset occupancy rate. In the case where an occupancy rate of the actual storage unit 800 is obtained a plurality of times, the monitoring system 301 may be configured to obtain a representative value such as an average value of occupancy rates of the actual storage unit 800 to comparison with the third preset occupancy rate, and compare the obtained representative value with the third preset occupancy rate.

Based on the fourth comparison information, when an occupancy rate of the actual storage unit 800 is less than the third preset occupancy rate, the monitoring system 301 may be configured to return to the previous operation again and obtain an occupancy rate of the actual storage unit 800 through the sensing system 400 and the like (S214).

On the contrary, based on the fourth comparison information, when an occupancy rate of the actual storage unit 800 is greater than or equal to the third preset occupancy rate, the monitoring system 301 may be configured to create feedback data (S218) and transmit the created feedback data to a network (S219). As an example, the feedback data may be transferred to the simulation server 500 or the DB of the simulation server 500 and stored therein.

The feedback data may be data for updating history data to increase a maximum storage capacity of the actual storage unit 800 when an occupancy rate of the actual storage unit 800 is greater than or equal to the third preset occupancy rate. The history data is updated by the feedback data, and the simulation server 500 may be configured to perform simulation based on the updated history data.

The actual storage unit 800 is installed to the site where the manufacturing process is performed and occupies a space and a user or an engineer should be put into the site to change a maximum storage capacity of the actual storage unit 800. In the case where a user or an engineer is put to the site, the entire manufacturing process is delayed or some of the processes should be stopped temporarily. Accordingly, it is important to predict and secure an appropriate storage capacity in advance. When simulation is performed in advance through the simulation server 500 as in an embodiment, not only a maximum storage capacity of the actual storage unit 800 for maintaining an occupancy rate of the actual storage unit 800 between about 60% to about 80% may be predicted but also constant update and feedback is possible by reflecting feedback data created in the site into the history data. More accurate simulation results may be derived through constant data update and feedback, and the above issues may be solved through this.

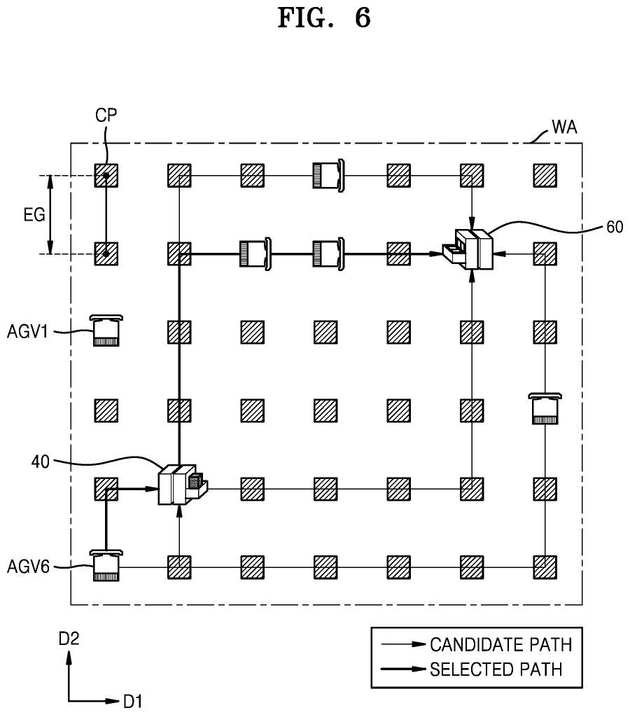

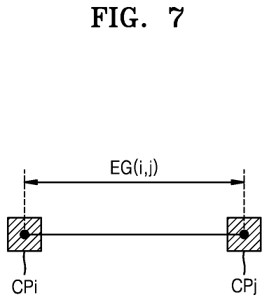

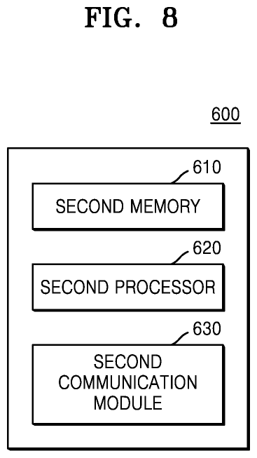

FIGS. 6 and 7 are schematic views for explaining a scenario of controlling a path of an automated guided vehicle at an AGV control server of FIG. 1, and FIG. 8 is a schematic conceptual view of the AGV control server of FIG. 1.

As shown in FIG. 6, the automated guided vehicle 700 may be configured to carry work in the process inside a work area WA. A plurality of nodes CP may be arranged at a preset interval inside the work area WA. The node CP is a control point through which the automated guided vehicle 700 passes, and the automated guided vehicle 700 may go straight from the node CP in the original driving direction, or turn right or left to change the driving direction. The automated guided vehicle 700 may not perform backward motion.

In an embodiment, a quick response (“QR”) code may be attached to each node CP. That is, the nodes CP may be configured (or implemented) using an identification means such as a QR code and the like. Each of the nodes CP may be identified using an identification means such as a QR code and the like. In another embodiment, the node CP may be configured (or implemented) using an RFID tag, a bar code, a Beacon, and the like. A first storage unit 40 and a second storage unit 60 may be located on some of the nodes CP, wherein the automated guided vehicle 700 moves work in the process and stores the same in the first storage unit 40, and the automated guided vehicle 700 moves work in the process and stores the same in the second storage unit 60.

Sensing means such as an acoustic sensor and a camera may be provided to a preset position in the work area WA to obtain state data (situation information) of the work area WA. The state data may include presence or absence of an obstacle on a path on which the automated guided vehicle 700 is travelling within the work area WA, and congestion due to a state of an obstacle, for example, a failure/accident of an obstacle, road recovery, and the like. Obstacles may include people, other automated guided vehicles, other types of vehicles, cargo that has fallen on the road, and damage to the road.

The automated guided vehicle 700 may communicate with the AGV control server 600 through a wired and/or wireless network. In an embodiment, the automated guided vehicle 700 may have a lidar, a short distance sensor, an ultraviolet sensor, an acoustic sensor and/or a camera, and be configured to obtain surrounding information using them.

The automated guided vehicle 700 may be configured to transmit state data of the vehicle, such as a current position, a current state, and driving speed, to the AGV control server 600 in real time or periodically. The automated guided vehicle 700 may start from a node at a current position to move to a node of the first storage unit 40 via at least one node, and move from the first storage unit 40 to a node of the second storage unit 60 via at least one node. Hereinafter, a straight line connecting centers of two adjacent nodes CP in a first direction D1 or a second direction D2 is referred to as an edge EG.

In the present specification, although the current position of the automated guided vehicle 700 is used as a term representing a geographical position at which the automated guided vehicle 700 is currently located, the current position may be understood as concept including a node corresponding to the current position of the automated guided vehicle 700. As an example, position data of the current position of the automated guided vehicle 700 may mean current geographical position data of the automated guided vehicle 700 or mean position data of a node corresponding to the current position. A node (referred to as a ‘current node’, hereinafter) corresponding to the current position may mean a node most adjacent to the current position or a node convenient to access from the current position.

The automated guided vehicle 700 may be configured to receive path data from the AGV control server 600 and move on nodes according to the path data. The path data may include position data of a node (the next node) to which the automated guided vehicle 700 is to move from a current node. The automated guided vehicle 700 may maintain a driving direction to move to the next node, or change a driving direction to move to the next node. Accordingly, the automated guided vehicle 700 may be configured to move along a selected path among a plurality of candidate paths. A selected path may be succession of edges EG connecting nodes CP on which the automated guided vehicle 700 actually moves.

As an example, FIG. 6 shows a first selected path where a sixth automated guided vehicle AGV6 starts from a currently located node and moves to a node of the first storage unit 40, and a second selected path where the sixth automated guided vehicle AGV6 starts from the node of the first storage unit 40 and moves to a node CP of the second storage unit 60.

The AGV control server 600 may be a control system configured to monitor and manage the movement of the automated guided vehicle 700. The automated guided vehicle 700 may be configured to control a driving path of the automated guided vehicle 700 based on state data received from the sensing means within the work area WA and/or the automated guided vehicle 700. The AGV control server 600 may be configured to communicate with the automated guided vehicle 700 by wire and/or wirelessly through a network. The AGV control server 600 may be configured to store received state data.

As shown in FIG. 7, the AGV control server 600 may be configured to calculate a travel time prediction value at each node CP based on the state data. The AGV control server 600 may be configured to predict a travel time taken for the automated guided vehicle 700 to travel from a node CPi to a node CPj. The node CPi is a candidate node to which the automated guided vehicle 700 may move from the node CPi, and the candidate node may be one or two or more.

The AGV control server 600 may be configured to select a node CPj having a smallest predicted travel time value among at least one node CPj (candidate node). The AGV control server 600 may be configured to transmit position data of the node CPj to a relevant automated guided vehicle 700.

The AGV control server 600 may be configured to control the driving path of the automated guided vehicle 700 to avoid obstacles without collision between the automated guided vehicles 700 and perform tasks in a shortest time. The AGV control server 600 may be configured to select the next node to pass through to a destination based on the travel time using state data and control a driving path of the automated guided vehicle 700 such as moving straight ahead, turnings and moving straight ahead, stopping moving, or moving at a reduced speed.

As shown in FIG. 8, the AGV control server 600 according to an embodiment may include a second memory 610, a second processor 620, and a second communication module 630, wherein the second memory 610 stores commands, the second processor 620 performs calculations based on the commands, and the second communication module 630 communicates with external apparatuses under control of the second processor 620. In this case, the external apparatus may denote the automated guided vehicle 700. In this case, because descriptions of the second memory 610, the second processor 620, and the second communication module 630 are the same as or redundant with the descriptions of the first memory 511, the first processor 512, and the first communication module 513 described above with reference to FIG. 2, the descriptions thereof are omitted.

In addition, although not shown, the AGV control server 600 may be connected to an input unit and an output unit through a wire and/or wirelessly. The input unit may be a user interface such as a key pad, a dome switch, a touch pad (a contact capacitance method, a pressure resistance film method, an infrared sensing method, a surface ultrasonic conduction method, an integral tension measurement method, a piezo effect method, and the like), a mouse, a remote controller, a jog wheel, a jog switch, and the like. The output unit may include a display. The display allows an operator to monitor displayed images by providing result images output from the AGV control server 600. The display may provide an operator with visual information and/or audible information for grasping the work area and the position and movement of the automated guided vehicle 700 moving within the work area. The display may be a computer screen, a TV screen, a mobile terminal screen, or a projector. In the case where the display is a touchscreen, the touchscreen may serve as an input unit.

An example of an operation scenario of the AGV control server 600 configured to control at least one automated guided vehicle 700 based on result data is described below.

As described above, the monitoring system 301 may be configured to receive result data from the simulation server 500 and create installation information data based on the result data. The AGV control server 600 may be configured to receive information on a maximum storage capacity of the actual storage unit 800 from the monitoring system 301. That is, the AGV control server 600 controls the automated guided vehicle 700 to carry work in the process to the actual storage unit 800, and may control the automated guided vehicle 700 based on the maximum storage capacity of the actual storage unit 800. As an example, in the case where a maximum storage capacity of the actual storage unit 800 is 10 and a real-time occupancy rate of the actual storage unit 800 is 9 or 10, the AGV control server 600 may be configured to control the automated guided vehicle 700 to carry work in the process to another storage unit (not shown) or control the automated guided vehicle 700 to stop carrying.

In this case, the other storage unit (not shown) is another storage unit (not shown) located farther away from the above-described actual storage unit 800 or located around preset position coordinates, and may denote the actual storage unit 800 having an occupancy rate less than a preset value. The AGV control server 600 may be configured to control the automated guided vehicle 700 to carry work in the process to another storage unit (not shown) based on result data and a real-time occupancy rate of the actual storage unit 800.

According to an embodiment, a simulation server based on digital twin and a management system of manufacturing logistics using the same to improve logistics efficiency in a manufacturing process may be implemented. However, the scope of the disclosure is not limited by this effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A simulation server comprising:
a database configured to store history data including an occupancy rate of an actual storage unit, wherein the database includes image data for a virtual storage unit corresponding to the actual storage unit to perform simulation by using a digital twin; and
a simulator apparatus configured to perform the simulation based on the history data and the image data,
wherein the simulator apparatus is further configured to obtain a change amount of an occupancy rate of the virtual storage unit during the simulation, and change or maintain a maximum storage capacity of the virtual storage unit based on the change amount.

2. The simulation server of claim 1, wherein the history data is information about the occupancy rate of the actual storage unit over time, and is obtained before a reference point-in-time.

3. The simulation server of claim 1, wherein the actual storage unit includes a plurality of storage modules, the image data for the virtual storage unit includes module image data corresponding to the plurality of storage modules, respectively, and the module image data is added to or removed from the simulation.

4. The simulation server of claim 3, wherein the maximum storage capacity of the virtual storage unit is proportional to a total number of the module image data during the simulation.

5. The simulation server of claim 3, wherein the simulator apparatus is further configured to obtain first comparison information of the occupancy rate of the virtual storage unit and a first preset occupancy rate after a reference time elapses during the simulation, and change a total number of the module image data during the simulation based on the first comparison information.

6. The simulation server of claim 5, wherein, when the occupancy rate of the virtual storage unit is less than the first preset occupancy rate after the reference time elapses during the simulation, the simulator apparatus is further configured to reduce the total number of the module image data during the simulation.

7. The simulation server of claim 5, wherein, when the occupancy rate of the virtual storage unit is greater than the first preset occupancy rate after the reference time elapses during the simulation, the simulator apparatus is further configured to obtain second comparison information of an occupancy rate of the virtual storage unit and a second preset occupancy rate.

8. The simulation server of claim 7, wherein the second preset occupancy rate is greater than the first preset occupancy rate.

9. The simulation server of claim 8, wherein, when the occupancy rate of the virtual storage unit is less than the second preset occupancy rate after the reference time elapses during the simulation, the simulator apparatus is further configured to maintain the maximum storage capacity of the virtual storage unit.

10. The simulation server of claim 8, wherein, when the occupancy rate of the virtual storage unit is greater than the second preset occupancy rate after the reference time elapses during the simulation, the simulator apparatus is further configured to increase the total number of the module image data during the simulation.

11. A management system for manufacturing logistics, the management system comprising:
a sensing system configured to obtain, over time, occupancy state information of each of a plurality of storage modules constituting an actual storage unit located in a preset area;
a simulation server including a database configured to store history data including the occupancy state information obtained over time, wherein the database includes image data for a virtual storage unit corresponding to the actual storage unit, and a simulator apparatus configured to perform digital twin-based simulation based on the history data and the image data; and
a monitoring system configured to output the digital twin-based simulation,
wherein the simulator apparatus is further configured to obtain a change amount of an occupancy rate of the virtual storage unit during the simulation, change or maintain a maximum storage capacity of the virtual storage unit based on the change amount, and create result data including the changed or maintained maximum storage capacity, and
the monitoring system is further configured to output the result data.

12. The management system of claim 11, further comprising:
at least one automated guided vehicle (AGV) configured to travel in the preset area; and
an AGV control server configured to control the at least one automated guided vehicle.

13. The management system of claim 11, wherein the history data is information of an occupancy rate of the actual storage unit over time and is obtained before a reference point-in-time.

14. The management system of claim 11, wherein the actual storage unit includes the plurality of storage modules, the image data for the virtual storage unit includes module image data corresponding to the plurality of storage modules, respectively, and the module image data is added to or removed from the simulation.

15. The management system of claim 11, wherein the maximum storage capacity is proportional to a total number of module image data during the simulation.

16. The management system of claim 11, wherein the simulator apparatus is further configured to obtain first comparison information of the occupancy rate of the virtual storage unit and a first preset occupancy rate after a reference time elapses during the simulation, and change a total number of the module image data during the simulation based on the first comparison information.

17. The management system of claim 16, wherein, when the occupancy rate of the virtual storage unit is less than the first preset occupancy rate after the reference time elapses during the simulation, the simulator apparatus is further configured to reduce the total number of the module image data during the simulation.

18. The management system of claim 16, wherein, when the occupancy rate of the virtual storage unit is greater than the first preset occupancy rate after the reference time elapses during the simulation, the simulator apparatus is further configured to obtain second comparison information of the occupancy rate of the virtual storage unit and a second preset occupancy rate after the reference time elapses during the simulation.

19. The management system of claim 18, wherein the second preset occupancy rate is greater than the first preset occupancy rate.

20. The management system of claim 19, wherein, when the occupancy rate of the virtual storage unit is less than the second preset occupancy rate after the reference time elapses during the simulation, the simulator apparatus is further configured to transfer the maximum storage capacity to the monitoring system, and the monitoring system is configured to output the maximum storage capacity.

21. The management system of claim 19, wherein, when the occupancy rate of the virtual storage unit is greater than the second preset occupancy rate after the reference time elapses during the simulation, the simulator apparatus is further configured to increase the total number of the module image data.

22. The management system of claim 11, wherein the monitoring system is configured to perform a manufacturing process that uses the actual storage unit changed based on the result data, and receive an occupancy rate of the actual storage unit while performing the manufacturing process.

23. The management system of claim 22, wherein the monitoring system is further configured to obtain third comparison information of the occupancy rate of the actual storage unit and a third preset occupancy rate while performing the manufacturing process, and control driving of target equipment or create feedback data based on the third comparison information.
